(19) United States
(12) Patent Application Publication
(10) Pub. No.: US 2023/0059848 A1
(43) Pub. Date: Feb. 23, 2023

(54) THROUGH WAFER TRENCH ISOLATION

(71) Applicant: TEXAS INSTRUMENTS INCORPORATED, Dallas, TX (US)

(72) Inventors: Scott Robert Summerfelt, Garland, TX (US); Benjamin Stassen Cook, Los Gatos, CA (US); Simon Joshua Jacobs, Allen, TX (US); Stefan Herzer, Marzling (DE)

(21) Appl. No.: 17/828,356

(22) Filed: May 31, 2022

Related U.S. Application Data
(60) Provisional application No. 63/235,084, filed on Aug. 19, 2021.

(51) Int. Cl. H01L 23/48; H01L 25/065; H01L 21/768

(52) U.S. Cl. CPC H01L 23/481; H01L 25/0657; H01L 21/76898; H01L 2225/06513; H01L 2225/06541; H01L 2225/06582

(57) ABSTRACT

A device includes a die with a metallization stack. The device includes a substrate with a first region, a second region and a third region that underly the metallization stack and a first isolation trench filled with a polymer dielectric that extends between the first region and the second region of the substrate. The device also includes a second isolation trench filled with the polymer dielectric that extends between the second region and the third region. The polymer dielectric overlays a periphery of the substrate.

### CROSS-REFERENCE TO RELATED APPLICATION

This application claims the benefit of priority to U.S. Provisional Application No. 63/235,084, filed on 19 Aug. 2021 the entirety of which is herein incorporated by reference.

### TECHNICAL FIELD

This description relates to dies. More particularly, this description relates to dies with a through trench for isolation between regions of the dies.

### BACKGROUND

In electronics, a wafer (also called a slice) is a thin slice of semiconductor, such as a crystalline silicon (c-Si), used for the fabrication of integrated circuits (ICs). The wafer serves as the substrate for microelectronic devices built in and upon the wafer. A wafer undergoes many microfabrication processes, such as doping, ion implantation, etching, thin-film deposition of various materials, and photolithographic patterning. Finally, the individual dies that include microcircuits are separated by wafer dicing and packaged as an integrated circuit.

Parylene is an organic polymer that includes hydrogen (H) and carbon (C) atoms. Parylene is hydrophobic and resistant to most chemicals. Coatings of parylene are often applied to electronic circuits and other equipment as electrical insulation, moisture barriers, or protection against corrosion and chemical attack. Parylene coatings are applied by chemical vapor deposition in an atmosphere of the monomer para-xylylene.

### SUMMARY

A first example relates to a device that includes a die with a metallization stack. The device has a substrate with a first region, a second region and a third region that underly the metallization stack. The device includes a first isolation trench filled with a polymer dielectric that extends between the first region and the second region of the substrate. The die also includes a second isolation trench filled with the polymer dielectric that extends between the second region and the third region, wherein the polymer dielectric overlays a periphery of the substrate.

A second example relates to a method for forming a die for an IC chip. The method includes depositing a polymer dielectric on a wafer. The wafer includes regions of substrates. The regions of substrates are separated by trenches of a first width, a second width or a third width, the first width being less than the second width, and the second width being less than the third width. A recess of the polymer dielectric is formed in the through trenches of the first width and the second width. The through trenches of the second width and the third width are etched to expose a metallization stack. Through vias are formed in the trenches of the second width. The method further includes singulating dies by cutting the wafer at the trenches of the third width such that the dies include the trenches of the second width and through vias formed in the trenches of the third width.

### BRIEF DESCRIPTION OF THE DRAWINGS

FIG. 1 illustrates a diagram of a die with isolation trenches filled with a polymer dielectric.

FIG. 2 illustrates a diagram of an example of a die with isolation trenches and a through via.

FIG. 3 illustrates an example of an integrated circuit chip that includes two dies.

FIG. 4A illustrates an overhead view of an example wafer with isolation trenches and die separation trenches.

FIG. 4B illustrates a cross-sectional view of the wafer of FIG. 4A.

FIG. 5A illustrates an overhead view of another example wafer with isolation trenches and die separation trenches.

FIG. 5B illustrates a cross-sectional view of the wafer of FIG. 5A.

FIG. 6A illustrates an overhead view of yet another example wafer with isolation trenches and die separation trenches.

FIG. 6B illustrates a cross-sectional view of the wafer of FIG. 6A.

FIG. 7 illustrates a first stage of a method for processing a wafer for singulation of dies.

FIG. 8 illustrates a second stage of the method for processing a wafer for singulation of dies.

FIG. 9 illustrates a third stage of the method for processing a wafer for singulation of dies.

FIG. 10 illustrates a fourth stage of the method for processing a wafer for singulation of dies.

FIG. 11 illustrates a fifth stage of the method for processing a wafer for singulation of dies.

FIG. 12 illustrates a sixth stage of the method for processing a wafer for singulation of dies.

FIG. 13 illustrates a seventh stage of the method for processing a wafer for singulation of dies.

FIG. 14 illustrates an eight stage of the method for processing a wafer for singulation of dies.

FIG. 15 illustrates a first stage of another method for processing a wafer for singulation of dies.

FIG. 16 illustrates a second stage of the other method for processing a wafer for singulation of dies.

FIG. 17 illustrates a third stage of the other method for processing a wafer for singulation of dies.

FIG. 18 illustrates a fourth stage of the other method for processing a wafer for singulation of dies.

FIG. 19 illustrates a fifth stage of the other method for processing a wafer for singulation of dies.

FIG. 20 illustrates a sixth stage of the other method for processing a wafer for singulation of dies.

FIG. 21 illustrates a seventh stage of the other method for processing a wafer for singulation of dies.

FIG. 22 illustrates an eight stage of the other method for processing a wafer for singulation of dies.

FIG. 23 illustrates a flowchart of an example method for processing a wafer to form IC chips.

### DETAILED DESCRIPTION

This description relates to a die for an IC chip (e.g., a device) and a method for forming the die. The method includes thinning a wafer with multiple instances of the die and placing the wafer so that a front surface is down on a silicon (Si) carrier wafer or tape on frame for further processing. The wafer is thinned either before or after the thinning. In some examples, a dielectric layer is deposited on a backside of the thinned wafer. In various examples, the dielectric layer is silicon nitride (SiN), silicon dioxide (SiO₂), spin on glass, hydrogen silsesquioxane (HSQ), silicon oxynitride (SiON), silicon carbide (SiC), silicon carbon oxynitride (SiCON), aluminum nitride (AlN), aluminum oxide (Al₂O₃), boron nitride (BN), diamond like carbon or a polymer such as polyimide or parylene. The backside of the thinned wafer is patterned and trenches are etched in the wafer to form regions of substrates. In some examples, the trenches are etched through the wafer stopping on or in the dielectrics on the frontside of the silicon wafer. The substrate (e.g., silicon substrate) include circuit components (e.g., transistors, diodes, resistors and/or capacitors, metal layers with vias for interconnect) embedded therein. In some examples, the top surface of the substrate includes multilayers of dielectrics and patterned metals used to form devices. Such multilayers of dielectrics enable fabrication of a device in a package such as solder covered copper (Cu), solder balls on copper (Cu) pads, gold (Au) studs, aluminum (Al) pads, copper (Cu) pads, palladium nickel (PdNi) pads, solder covered copper (Cu) plus and/or other options. These features enable different types of packages for which the device is usable. The regions of substrates are separated by through trenches of a first width, a second width or a third width. The first width is less than the second width and the second width is less than the third width. The through trenches of the first width are referred to as isolation trenches, the through trenches of the second width are referred to as via trenches and the through trenches of the third width are referred to as die separation trenches.

A polymer dielectric (e.g., parylene) is deposited on the wafer. The through trenches are shaped such that a recess of the polymer dielectric is formed in the via trenches and the die separation trenches. The isolation trenches are filled and have a smaller depth than the recess of the polymer dielectric formed in the via trenches and the die separation trenches. The removal of the polymer dielectric in the trenches for die separation and via trenches exposes material beyond the substrate. The die separation trenches and the via trenches are etched to expose an underlying metallization stack, and the isolation trenches are not etched. In various examples, this etching of the die separation trenches and the via trenches is done using a patterned etch with mask layer before the etch or by using an anisotropic etch where a layer of polymer dielectric is removed vertically but a small amount (e.g., 0-5%) horizontally. In the non-patterned situation, the polymer dielectric is thinned roughly the same amount vertically. In the example of the non-patterned dielectric etch, the polymer is removed above the substrate exposing the dielectric layer (if present). In this way, through vias are formed in the via trenches by filling the via trenches with a conductive metal (e.g., with electroplating), and solder balls are attached to the through vias. The dies are then singulated from the wafer by cutting the die singulation trenches such that the dies include the through vias and the isolation trenches. The singulation is executable with a selected technique. In some examples, the polymer is not removed and the die are separated mechanically. For instance, in at least one example, mechanical separation is executed with a rolling technique and/or a stretch technique at room temperature or low temperatures (e.g., about 97 kelvin (K) or less). Low temperature is employed in situations where the polymer remains because the polymer becomes more brittle and less ductile at lower temperatures. Another technique includes removing the polymer in a singulation region through laser etching either from the frontside or the backside. In various examples, this laser etching removes just the polymer followed by mechanical separation or the laser etching removes or fractures the polymer as well as the dielectrics and metals in the singulation region. The dies, once singulated are packaged, such that the dies are mounted on an interconnect and encased in molding. By employing the method described herein, the polymer dielectric is employable to fill the isolation trenches, and enable formation of the through vias. Also, the polymer dielectric facilitates the singulation of the dies.

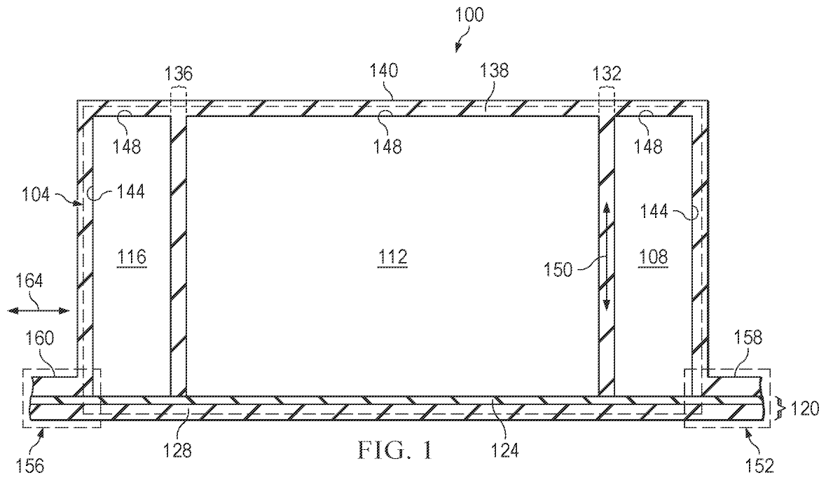

FIG. 1 illustrates a cross-section diagram of a region of a die 100 employable for an integrated circuit (IC) chip (e.g., a device). The die 100 has been singulated from a wafer. The die 100 includes a substrate 104. The substrate 104 is formed of a semiconductor material such as silicon (Si), in some examples. The substrate 104 includes a first region 108, a second region 112 and a third region 116. A metallization stack 120 underlays the substrate 104. The metallization stack 120 includes a pre-metal dielectric (PMD) 124 and a protective overcoat (PO) 128. The pre-metal dielectric is frequently starts with PMD barrier, usually SiN, followed by oxide such as phosphorous silicate glass (PSG) that was planarized then capped with undoped SiO2, like TEOS SiO2, before metallization layers with the corresponding dielectric layers. These dielectric layers are implemented SiO2 or low-K dielectrics such as SiOCOH. Some such oxide type layers are deposited using plasma enhanced chemical vapor deposition (PECVD). In a simple example, employs PECVD using TEOS plus O2 to create SiO2. Metal layers are usually Al usually with W vias or possibly Cu metal layers and vias. Contact to the usually silicided doped Si substrate 104 is usually using W contact with Ti and TIN barrier layers. In some such examples, the metallization stack 120 is fabricated using one or more layers of patterned metal, such as aluminum (Al) or copper (Cu). In some such examples, Aluminum (Al) metal layers employ vias formed with a metal such as tungsten (W) to enable electrical communication between different layers of the metallization stack 120. Both of these usually use Ti and TiN as adhesion promoters or diffusion barriers. In some such examples, copper (Cu) layers are fabricated with the damascene approach and the vias are between copper (Cu) layers are also formed of copper (Cu). Copper frequently uses Ta or TaN as a conductive diffusion barrier and SiN or SiCN as an insulating diffusion barrier above or possible above and below.

The PMD 124 underlies the substrate 104 and the PO 128 underlies the PMD 124. In such a situation, the PO 128 is opened to expose pads of an interconnect (e.g., a lead frame) for the IC chip. In some examples, the PMD barrier 124 is formed from a dielectric material, such as silicon nitride (SiN) and/or silicon dioxide (SiO₂), also referred to as silica. In other examples, the PMD 124 is formed with phosphosilicate glass (PSG), or borophosphosilicate glass (BPSG) with undoped SiO2 as well. In other examples, the dielectric stack 128 includes SiN, fluorine doped SiO₂ or a low-K dielectric such as SiOHC—maybe AMAT Black Diamond, or others such as silsesquioxane [RSiO_{3/2}]ₙ. In some examples, the PO 128 is formed with silicon oxynitride (SiON) or silicon nitride (SiN). Some devices have additional metal layers that employ copper (Cu) and a polymeric dielectric such as polyimide.

The first region 108, the second region 112 and the third region 116 contain circuit components (e.g., transistors, resistors, capacitors, etc.) formed with standard processing techniques. The first region 108 and the second region 112 are spaced apart by a first isolation trench 132. The second region 112 and the third region 116 are separated by a second isolation trench 136. It is possible that the first region 108 and the third region 116 are connected using the substrate. Many regions could all be isolated using the trenches. The first isolation trench 132 is a through trench that provides dielectric isolation between the first region 108 and the second region 112 of the substrate 104. Similarly, the second isolation trench 136 provides dielectric isolation between the second region 112 and the third region 116. In this manner, in some examples, the first region 108, the second region 112 and the third region 116 have different power domains. As one example, the first region 108 and the third region 116 have a high supply voltage (e.g., 80 V or more), wherein some of the components integrated with the first region 108 and/or the third region 116 are rated for the high supply voltage. Conversely, in this example, the second region 112 has a low supply voltage (e.g., 10 V or less), wherein components integrated with the second region 112 of the substrate 104 are rated for the low supply voltage. Inclusion of the first isolation trench 132 and the second isolation trench 136 prevents unwanted electromagnetic interference (EMI) leaking and/or shorts between the three power domains. It is possible that in some cases the regions are isolated using more than one trench features. By doing this lower capacitance and potentially higher voltage isolation might be achieved at the cost of a higher area.

The first isolation trench 132 and the second isolation trench 136 are filled with a polymer dielectric 138, such as parylene, including some of the functional groups of parylene, such as parylene-F, parylene-HT, parylene-VT4 or parylene-AF4. A periphery 140 of the substrate 104 is also circumscribed by the polymer dielectric 138. Stated differently, sidewalls 144 and a surface 148 of the first region 108, the second region 112 and the third region 116 of the substrate 104 are covered with the polymer dielectric 138.

The first isolation trench 132 and the second isolation trench 136 extend in a first direction indicated by arrows 150 between the surface 148 and the metallization stack 120. The metallization stack 120 includes a first extended region 152 and a second extended region 156 that extends beyond the sidewalls 144 of the substrate 104. The polymer dielectric 138 underlies the first extended region 152 and the second extended region 156. More particularly, a first extension 158 of the polymer dielectric 138 overlies the first extended region 152, and a second extension 160 of the polymer dielectric 138 overlies the second extended region 156 of the metallization stack 120.

The first extended region 152 and the second extended region 156 extend in a second direction indicated by arrows 164. The second direction (indicated by the arrows 164) is perpendicular to the first direction (indicated by the arrows 150). The first extended region 152 of the metallization stack 120 and the first extension 158 of the polymer dielectric 138 are formed from singulation of the die 100. Similarly, the second extended region 156 of the metallization stack 120 and the second extension 160 of the polymer dielectric 138 are also formed from singulation of the die 100.

As illustrated, the die 100 includes isolation trenches, namely, the first isolation trench 132 and the second isolation trench 136 filled with the polymer dielectric 138. Also, the polymer dielectric 138 underlies the first extended region 152 and the second extended region 156 (with the respective first extension 158 and the second extension 160). Accordingly, the polymer dielectric 138 is employable to form the isolation trenches and to facilitate singulation of the die 100.

In various examples, the die 100 is separated with an additional operation, such as a mechanical saw, laser saw, laser stealth or stress dicing such as Maho or employing the trench etch operation as shown in FIG. 1. As illustrated in FIG. 1, the second extension 160 illustrates an example where the trench is wider as shown in arrows 164 and hence the parylene deposition has not filled the trench but instead is on sides and a bottom of the die 100. In such a situation, a thin protective overcoat (or metal) of dielectrics overlaying the backside trench dielectric are present between instances the die 100. In this manner, the die 100 is separatable from other dies on a common wafer using a number of techniques. These techniques include, but are not limited to mechanical saw, laser saw, or mechanical separation using spreadable tape, mechanical bending, water spray or one of more of these in combination. In some examples, the mechanical separation is enhanced by being executed at lower temperature (e.g., less than about 300 Kelvin) where polymeric trench dielectrics become brittle and separable.

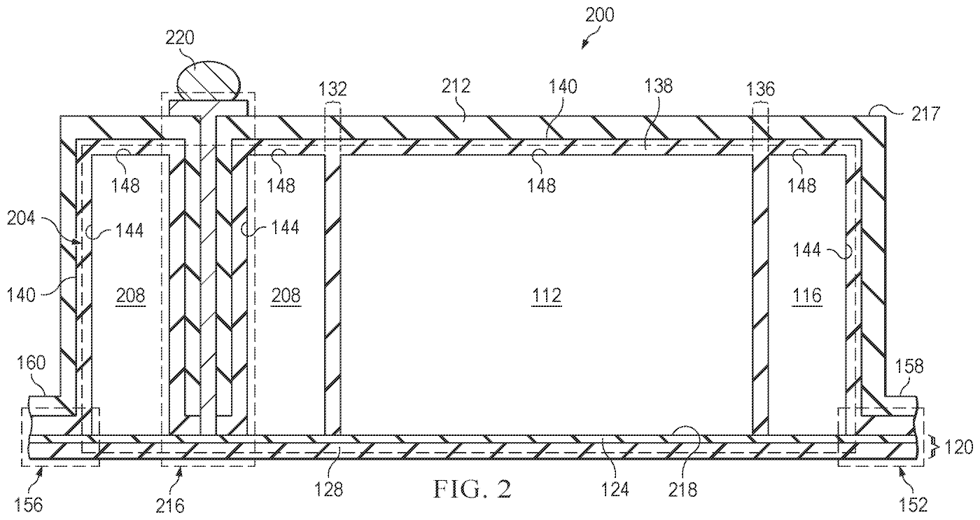

FIG. 2 illustrates a cross-section diagram of a region of a die 200 employable for an IC chip (a device). For simplicity, FIGS. 1 and 2 employ the same reference numbers to denote the same structure. Moreover, some reference numbers are not reintroduced. The die 200 has been singulated from a wafer. The die 200 includes a substrate 204. The substrate is formed of a semiconductor material such as silicon (Si). The substrate 204 is employable to implement an instance of the substrate 104 of FIG. 1. The substrate 204 includes a first region 208, the second region 112 and the third region 116. The metallization stack 120 underlays the substrate 204. The metallization stack 120 includes the PMD 124 and the PO 128. The PMD 124 underlies the substrate 204 and the PO 128 underlies the PMD 124.

The first region 208, the second region 112 and the third region 116 contain circuit components (e.g., transistors, resistors, capacitors, etc.) formed with standard processing techniques. The first region 208 and the second region 112 are spaced apart by a first isolation trench 132. The second region 112 and the third region 116 are separated by a second isolation trench 136. The first isolation trench 132 provides dielectric isolation between the first region 208 and the second region 112 of the substrate 104. Similarly, the second isolation trench 136 provides dielectric isolation between the second region 112 and the third region 116. In this manner, in some examples, the first region 208, the second region 112 and the third region 116 have different power domains. As one example, the first region 208 and the third region 116 have a high supply voltage (e.g., 80 V or more), wherein some of the components integrated with the first region 208 and/or the third region 116 are rated for the high supply voltage. Conversely, in this example, the second region 112 has a low supply voltage (e.g., 10 V or less), wherein components integrated with the second region 112 of the substrate 104 are rated for the low supply voltage. Inclusion of the first isolation trench 132 and the second isolation trench 136 prevents unwanted electromagnetic interference (EMI) leaking and/or shorts between the three power domains.

The first isolation trench 132 and the second isolation trench 136 are filled with the polymer dielectric 138, such as parylene. A periphery 140 of the substrate 104 is also circumscribed by the polymer dielectric 138. Stated differently, the sidewalls 144 and a surface 148 of the first region 108, the second region 112, the third region 116 and the first region 208 of the substrate 104 are covered with the polymer dielectric 138. In some examples, a rigid material 212 is added to overlay the polymer dielectric 138. In some cases the rigid layer can be under the polymer dielectric 138. The rigid material 212 adds strength to the die 200. The rigid material 212 is formed, for example, from a metal (e.g., aluminum) or a dielectric material. In other examples, the rigid material 212 is a dielectric material, such as silicon dioxide (SiO₂), silicon dioxide on silicon nitride (SiO₂ on SiN), silicon carbide (SiC), aluminum oxide (AlOₓ) or aluminum nitride (AlN). In some examples the rigid material 212 is omitted. In some cases an additional dielectric using similar materials listed above for the rigid material 212 is deposited on the backside of the substrate 204 before pattern end etching is executed to create the first isolation trench 132 and the second isolation trench 136. This additional dielectric increases a voltage rating of the backside the substrate 204 at different regions.

A through via 216 is situated in the first region 208. The first region 208 has two different sections in FIG. 2 to denote that the first region 208 circumscribes the through via 216. The through via 216 has a larger width than the first isolation trench 132 or the second isolation trench 136. Stated differently, the first isolation trench 132 and the second isolation trench 136 have substantially equal widths, namely a first width, and the through via 216 has a second width, greater than the first width. In at least one example, only if a first measurement is within five percent (5%) of a second measurement, then the first measurement is substantially equal to the second measurement.

The through via 216 provides a conductive path across the die 200. Stated differently, the through via 216 provides an electrical connection between a first surface 217 of the die 200 and a second surface 218 of the die 200, wherein the first surface 217 opposes the second surface 218. A solder ball 220 overlays the through via 216. Accordingly, the through via 216 provides a conductive path from the solder ball 220 to the metallization stack 120. The through via 216 includes a dielectric layer (e.g., a film) overlaying the rigid material 212 (if the rigid material 212 is included). The through via 216 is filled with a conductive material (e.g., copper) that is electroplated in the through via 216.

The first extension 158 of the polymer dielectric 138 overlays the first extended region 152. Similarly, the second extension 160 of the polymer dielectric 138 overlays the second extended region 156. Regions of the rigid material 212 overlays the first extension 158 and the second extension 160 of the polymer dielectric 138. These features extending beyond the substrate 204 are formed through a singulation process to singulate the die 200 from a wafer.

As illustrated, the die 200 includes isolation trenches, namely, the first isolation trench 132 and the second isolation trench 136 filled with the polymer dielectric 138. Furthermore, the die 200 includes the through via 216. Also, the polymer dielectric 138 overlies the first extended region 152 and the second extended region 156 (with the respective first extension 158 and the second extension 160). Accordingly, the polymer dielectric 138 is employable to form the isolation trenches, the through via 216 and to facilitate singulation of the die 200.

FIG. 3 illustrates an example of an IC chip 300 (a device) that includes a first die 304 and a second die 308. The second die 308 is mounted on a backside of the first die 304 in a stacked die configuration. The first die 304 is employable to implement an instance of the die 200 of FIG. 2. The IC chip 300 also includes an interconnect 312 that is employable to provide connection pads 316 for communication to external circuits. The interconnect 312 is alternatively referred to as a lead frame. The first die 304 includes a metallization stack 317 to provide connections to the interconnect 312. A molding 314 encases the first die 304 and the second die 308. The molding 314 is formed of plastic or other non-conductive material.

The first die 304 includes a substrate 318 with a first region 320, a second region 322, a third region 326, a fourth region 328 and a fifth region 332. The first region 320, the second region 322, the third region 326, the fourth region 328 and the fifth region 332 contain circuit components (e.g., transistors, resistors and/or capacitors) for the first die 304. The first region 320 and the second region 322 are separated by a first isolation trench 336. Similarly, the second region 322 and the third region 326 are separated by a second isolation trench 340 and the third region 326 and the fourth region 328 are separated by a third isolation trench 344. Still further, the fourth region 328 and the fifth region 332 are separated by a fourth isolation trench 348. The first isolation trench 336, the second isolation trench 340 and the third isolation trench 344 and the fourth isolation trench 348 are filled with a polymer dielectric, such as parylene. In some examples, a top surface of the substrates 318 includes multilayers of dielectrics and patterned metals used to form devices. Such multilayers of dielectrics enable fabrication of a device in a package such as solder covered copper (Cu), solder balls on copper (Cu) pads, gold (Au) studs, aluminum (Al) pads, copper (Cu) pads, palladium nickel (PdNi) pads, solder covered copper (Cu) plus and/or other options. These features enable different types of packages in which the resultant device is usable.

A first through via 352 is situated in the second region 322, such that the second region circumscribes the firth through via 352, and two regions are labeled as the second region 322. Similarly, a second through via 356 is situated in the fourth region 328, such that the fourth region 328 circumscribes the second through via 356. The second die 308 is coupled to the first through via 352, such that the second die 308 is coupled to the metallization stack 317 and to the interconnect 312. Also, the third region 326 of the substrate 318 of the first die 304 is coupled to the second die 308 with a backside etched region 362. The second through via 356 is coupled to a wire bond 366. In various examples, the wire bond 366 is coupled to another node, such as a connector pad of the second die 308 or to another die (not shown). The first through via 352 and the second through via 356 are filled with the polymer dielectric and a conductive material (e.g., copper).

As demonstrated by the IC chip 300, the first die 304 includes isolation trenches, namely, the first isolation trench 336, the second isolation trench 340, the third isolation trench 344 and the fourth isolation trench 348. Also, the first die 304 includes through vias, namely a first through via 352 and a second through via 356 that are formed with through trenches filled with the polymer dielectric. Further, the first die 304 is singulated from a wafer using standard processing techniques.

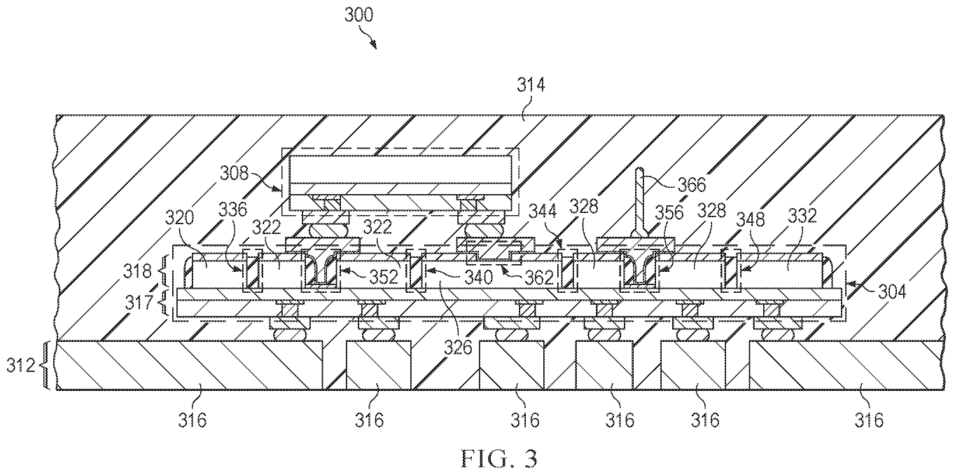

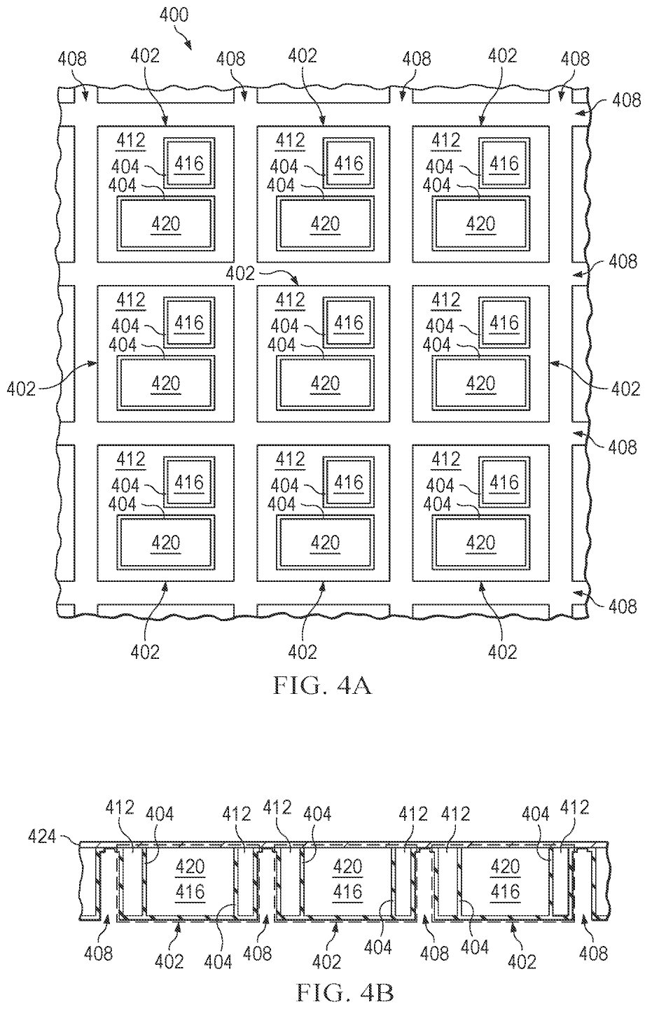

FIG. 4A illustrates an overhead view of a wafer 400 of substrates 402 with a isolation trenches 404 and die separation trenches 408 cut in the wafer 400. FIG. 4B illustrates a cross-sectional view of the wafer 400 of the substrates 402. Each substrate 402 includes a first region 412, a second region 416 and a third region 420. The second region 416 and the third region 420 of each substrate 402 are circumscribed by an isolation trench 404. Also, the first region 412 of the substrates 402 is circumscribed by the die separation trenches 408. In FIG. 4B, the first region 412 is illustrated at the edges of the substrates 402 and the second region 416 and the third region 420 are illustrated in a center region of the substrates 402.

In some examples, the wafer 400 is thinned and placed so that a front surface of the wafer is down on a silicon (Si) carrier wafer or tape on frame for further processing. In some examples, a dielectric layer is deposited on a backside of the wafer 400. In various examples, the dielectric layer is silicon nitride (SiN), silicon dioxide (SiO₂), spin on glass, hydrogen silsesquioxane (HSQ), silicon oxynitride (SiON), silicon carbide (SiC), silicon carbon oxynitride (SiCON), aluminum nitride (AlN), aluminum oxide (Al₂O₃), boron nitride (BN), diamond like carbon or a polymer such as polyimide or parylene. The backside of the wafer 400 is patterned and trenches are etched in the wafer 400 to form regions of substrates, such as the first region 412 that is illustrated at the edges of the substrates 402 and the second region 416 and the third region 420 that are illustrated in a center region of the substrates 402.

In some examples, a top surface of the substrates 402 include multilayers of dielectrics and patterned metals used to form devices. Such multilayers of dielectrics enable fabrication of a device in a package such as solder covered copper (Cu), solder balls on copper (Cu) pads, gold (Au) studs, aluminum (Al) pads, copper (Cu) pads, palladium nickel (PdNi) pads, solder covered copper (Cu) plus and/or other options. These features enable different types of packages with which the resultant device is usable.

The first region 412, the second region 416 and the third region 420 have embedded circuit components (e.g., transistors, resistors and/or capacitors). In some examples, the first region 412, the second region 416 and the third region 420 have different power levels (e.g., different voltage levels). As illustrated, the isolation trenches 404 have a first width, and the die separation trenches 408 have a second width, and the second width is greater than the first width. Also, in other examples, additional die separation trenches are employ to enable nesting. For instance, in some such examples, another trench is included within the second region 416 and/or the third region 420. Furthermore, in alternative examples, some die separation trenches 404 share a boundary of neighboring isolated regions. Using this approach enables the employment of complicated shapes for the isolated regions. Further still, in addition, the die isolation trenches 404 are employable to fabricate three-dimensional capacitors.

The wafer 400 is singulated into dies by cutting or etching polymer dielectric in the die separation trenches 408 to expose a metallization layer 424 that is cuttable in a similar manner. The example illustrated shows the polymer dielectric as being removed proximate the isolation trench 408. However, in other example, the die separation trenches 408 and the metallization layer 424 are removed or separated together. More particularly, using a laser, a plasma cutter or a mechanical process (e.g., sawing, stretching, bending or water spray), the die separation trenches 408 are cut to form dies, such as the die 100 of FIG. 1. In some examples of the singulation, the polymer is not removed and the substrates 402 are separated mechanically. For instance, in at least one example, mechanical separation is executed with a rolling technique and/or a stretch technique at room temperature or low temperatures (e.g., about 97 kelvin (K) or less). Low temperature is employed in situations where the polymer remains because the polymer becomes more brittle and less ductile at lower temperatures. Another technique includes removing the polymer in a singulation region through laser etching either from the frontside or the backside. In various examples, this laser etching removes just the polymer followed by mechanical separation or the laser etching removes or fractures the polymer as well as the dielectrics and metals in the singulation region.

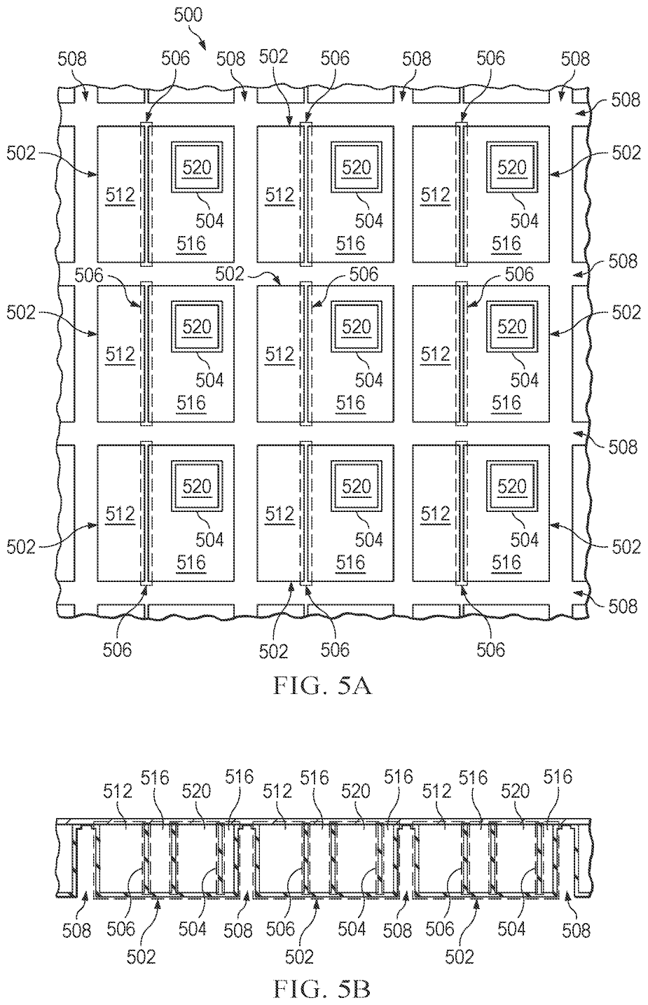

FIG. 5A illustrates an overhead view of a wafer 500 of substrates 502 with enclosing isolation trenches 504, edge isolation trenches 506 and die separation trenches 508 cut in the wafer 500. The enclosing isolation trenches 504, the edge isolation trenches 506 and the die separation trenches 508 are through trenches. FIG. 5B illustrates a cross-sectional view of the wafer 500 of the substrates 502. Each substrate 502 includes a first region 512, a second region 516 and a third region 520. The enclosing isolation trenches 504 have a rectangular shape such that the third region 520 of each substrate 502 is circumscribed by an enclosing isolation trench 504. FIG. 5B references the same features, namely the second region 516 and the enclosing isolation trenches 504 to denote that the third region 520 is circumscribed by the second region 516 and the enclosing isolation trenches 504. The edge isolation trenches 506 extends between edges of the substrates 502, such that the edge isolation trench 506 extends to two die separation trenches 508, and between the first region 512 and the second region 516 of the substrates 502. Accordingly, the edge isolation trench 506 is an isolation trench between the first region 512 and the second region 516. The edge isolation trenches 506 have a linear shape. Stated differently, the edge isolation trenches extend perpendicularly from a first edge to a second edge of the periphery of the substrates 502, and the first edge and the second edge are parallel.

In some examples, the wafer 500 is thinned and placed so that a front surface of the wafer is down on a silicon (Si) carrier wafer or tape on frame for further processing. In some examples, a dielectric layer is deposited on a backside of the wafer 500. In various examples, the dielectric layer is silicon nitride (SiN), silicon dioxide (SiO₂), spin on glass, hydrogen silsesquioxane (HSQ), silicon oxynitride (SiON), silicon carbide (SiC), silicon carbon oxynitride (SiCON), aluminum nitride (AlN), aluminum oxide (Al₂O₃), boron nitride (BN), diamond like carbon or a polymer such as polyimide or parylene. The backside of the wafer 500 is patterned so that enclosing isolation trenches 504 and the edge isolation trenches 506 are etched in the wafer 500 to form regions of substrates 502, such as the first region 512, the second region 516 of the substrates 502 is illustrated at the edges of the substrates 502 and the second region 516 and the third region 520 are illustrated in a center region of the substrates 502.

In some examples, a top surface of the substrates 502 include multilayers of dielectrics and patterned metals used to form devices. Such multilayers of dielectrics enable fabrication of a device in a package such as solder covered copper (Cu), solder balls on copper (Cu) pads, gold (Au) studs, aluminum (Al) pads, copper (Cu) pads, palladium nickel (PdNi) pads, solder covered copper (Cu) plus and/or other options. These features enable different types of packages in which the resultant device is usable.

The edge isolation trenches 506 and the enclosing isolation trenches 504 have a first width, and the die separation trenches 508 have a second width, greater than the first width. The edge isolation trenches 506, the enclosing isolation trenches 504 and the die separation trenches 508 are filled with a polymer dielectric (e.g., parylene). As illustrated in FIG. 5B, the die separation trenches 508 form cavities to facilitate singulation of the substrates 502 to form dies. In the example illustrated, the polymer dielectric is removed proximate the die separation trenches 508. In other examples, the die separation trenches 508 and the metallization stack 524 are removed or separated together. More generally, in some examples the polymer dielectric is removed (e.g., by cutting or etching) to enable separation of the substrates 502. In other examples of the singulation, the polymer is not removed and the substrates 502 are separated mechanically. For instance, in at least one example, mechanical separation is executed with a rolling technique and/or a stretch technique at room temperature or low temperatures (e.g., about 97 kelvin (K) or less). Low temperature is employed in situations where the polymer remains because the polymer becomes more brittle and less ductile at lower temperatures. Another technique includes removing the polymer in a singulation region through laser etching either from the frontside or the backside. In various examples, this laser etching removes just the polymer followed by mechanical separation or the laser etching removes or fractures the polymer as well as the dielectrics and metals in the singulation region.

Trench etch singulation, as illustrated in FIG. 5, ensures that an edge of singulated substrates 502 (forming dies) are covered by the insulating dielectric. Conversely, in conventional trench structures, an outside of a die needs to be the same voltage as an interior portion of the dies because a trench is not present at the edge of the die. Also, inclusion of the edge isolation trenches 506 enables the size of the substrates 502 to be reduced because different voltage regions are adjacent even at the edge of the substrates 502. Reducing the size of the substrates 502 enables a reduction of cost of manufacturing. Application such as high voltage applications (e.g., voltage ratings of about 300 V or more) are enabled because air and/or a plastic mold compound has a low electric field rating (e.g., about 100 to about 300 kV/cm).

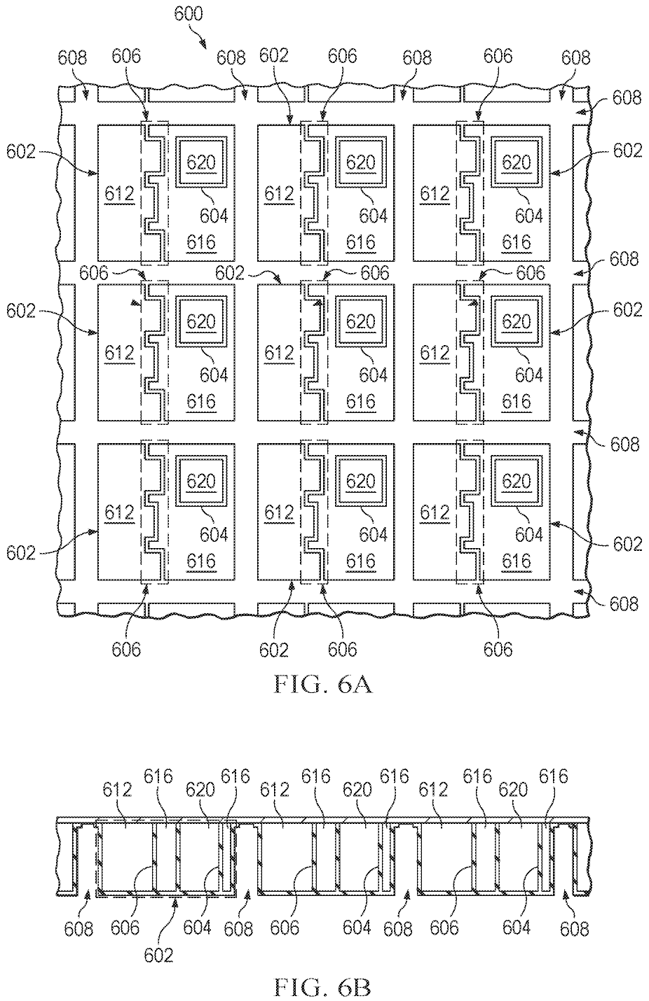

FIG. 6A illustrates an overhead view of a wafer 600 of substrates 602 with enclosing isolation trenches 604, edge isolation trenches 606 and die separation trenches 608 cut in the wafer 600. The enclosing isolation trenches 604, the edge isolation trenches 606 and the die separation trenches 608 are through trenches. FIG. 6B illustrates a cross-sectional view of the wafer 600 of the substrates 602. Each substrate 602 includes a first region 612, a second region 616 and a third region 620. In the example illustrated, the enclosing isolation trenches 604 have a rectangle shape such that the third region 620 of each substrate 602 is circumscribed by the enclosing isolation trenches 604. In other examples, other shapes are employable. Accordingly, the wafer 600 is agnostic to the shape of the enclosing isolation trenches 604.

In some examples, the wafer 600 is thinned and placed so that a front surface of the wafer is down on a silicon (Si) carrier wafer or tape on frame for further processing. In some examples, a dielectric layer is deposited on a backside of the wafer 600. In various examples, the dielectric layer is silicon nitride (SiN), silicon dioxide (SiO₂), spin on glass, hydrogen silsesquioxane (HSQ), silicon oxynitride (SiON), silicon carbide (SiC), silicon carbon oxynitride (SiCON), aluminum nitride (AlN), aluminum oxide (Al₂O₃), boron nitride (BN), diamond like carbon or a polymer such as polyimide or parylene. The backside of the wafer 600 is patterned so that enclosing isolation trenches 604 and the edge isolation trenches 606 are etched in the wafer 600 to form regions of substrates 602, such as the first region 612, the second region 616 and the third region 620.

In some examples, a top surface of the substrates 602 include multilayers of dielectrics and patterned metals used to form devices. Such multilayers of dielectrics enable fabrication of a device in a package such as solder covered copper (Cu), solder balls on copper (Cu) pads, gold (Au) studs, aluminum (Al) pads, copper (Cu) pads, palladium nickel (PdNi) pads, solder covered copper (Cu) plus and/or other options. These features enable different types of packages in which the resultant device is usable.

The enclosing isolation trench 604, which is an arbitrary shape is shown as a rectangular for simplicity so the third region 620 of each substrate 602 is circumscribed by an enclosing isolation trench 604. A wavy shape (e.g., a non-linear shape) for the edge isolation trenches 606 across a substrate 602 improves the mechanical strength of the two sections of the corresponding substrate 602. With a straight edge (e.g., a linear shape), such as the edge isolation trenches 506 of FIG. 5A, the mechanical strength of the first region 512 and second region 516 is dependent on an interface between a trench dielectric and the substrate 502 as well as a thin dielectric in a metallization of a circuit. FIG. 6B references the same features, namely the second region 616 and the enclosing isolation trenches 604 to denote that the third region 620 is circumscribed by the second region 616 and the enclosing isolation trenches 604. The edge isolation trenches 606 extends between edges of the substrates 602, such that the edge isolation trench 606 extends to two die separation trenches 608, and between the first region 612 and the second region 616 of the substrates 602. Accordingly, the edge isolation trench 606 is an isolation trench between the first region 612 and the second region 616. The edge isolation trenches 606 have a non-linear shape. Stated differently, the edge isolation trenches 606 extend from a first edge to a second edge of the substrates 602, but in a non-linear manner (e.g., a crooked line). The non-linear shape of the edge isolation trenches 606 enables efficient placement of circuit components within the first region 612 and/or the second region 616 of the substrates 402.

The edge isolation trenches 606 and the enclosing isolation trenches 604 have a first width, and the die separation trenches 608 have a second width, greater than the first width. The edge isolation trenches 606, the enclosing isolation trenches 604 and the die separation trenches 608 are filled with a polymer dielectric (e.g., parylene). As illustrated in FIG. 6B, the die separation trenches 608 form cavities to facilitate singulation of the substrates 602 to form dies. More particularly, in some examples, the polymer dielectric is removed (e.g., by cutting or etching) to enable separation of the substrates 602. In other examples of the singulation, the polymer is not removed and the substrates 602 are separated mechanically. For instance, in at least one example, mechanical separation is executed with a rolling technique and/or a stretch technique at room temperature or low temperatures (e.g., about 97 kelvin (K) or less). Low temperature is employed in situations where the polymer remains because the polymer becomes more brittle and less ductile at lower temperatures. Another technique includes removing the polymer in a singulation region through laser etching either from the frontside or the backside. In various examples, this laser etching removes just the polymer followed by mechanical separation or the laser etching removes or fractures the polymer as well as the dielectrics and metals in the singulation region.

FIGS. 7-14 illustrate stages of a method of processing a wafer for enabling three (3) capabilities. The first capability enables singulation of dies, such as the die 100 of FIG. 1, the die 200 of FIG. 2 or the first die 304 of FIG. 3. The second capability provides through wafer trench isolation. The third capability provides a through wafer metal interconnect. The method of FIGS. 7-14 illustrates how the wafer is processed to add through trenches for isolation trenches, through vias and die separation trenches for dies that are employable in an IC chip, such as the IC chip 300 of FIG. 3.

As illustrated in FIG. 7, at 700, in a first stage, a dielectric 800 such as silicon oxide (SiO₂), silicon nitride (SiN), silicon oxynitride (SiON), silicon carbide (SiC), aluminum oxide (AlOₓ) and/or aluminum nitride (AlN) is applied to a wafer 804 that includes substrates overlying a metallization stack 806. In response to the application of the dielectric 800, a surface of the dielectric is masked. In some examples, the surface is masked with a photodefinable polymer like resist. For example, the masking includes application of the resist coat, optical exposure to the resist coat using a direct write or mask operation. Also, the masking includes developing (patterning) the resist and baking (heating) the resultant structure. In some examples, in response to patterning the dielectric 800 with the resist patterning, the dielectric 800 and the substrate are etched using the same mask. In other examples, a separate mask is employed to pattern and etch the dielectric 800 and the substrate. Also, at 700, through trenches in the wafer 804 are formed (with the application of a photoresist and/or an etch) to provide regions of the substrates that are separated by the through trenches. The wafer 804 is employable to implement the wafer 500 of FIGS. 5A and 5B and/or the wafer 600 of FIGS. 6A and 6B.

The through trenches include die separation trenches 808, isolation trenches 812 and via trenches 816. As illustrated, the isolation trenches 812 have a first width, the via trenches 816 have a second width and the die separation trenches 808 have a third width, wherein the third width is greater than the second width, and the second width is greater than the first width. Forming the isolation trenches 812 with more narrow trenches (relative to the die separation trenches 808 and the via trenches 816) curtails metal penetrating into the isolation trenches 812. Conversely, a recess of the polymer dielectric 820 is formed in the die separation trenches 808 (trenches with the third width) and the via trenches 816 (trenches with the second width).

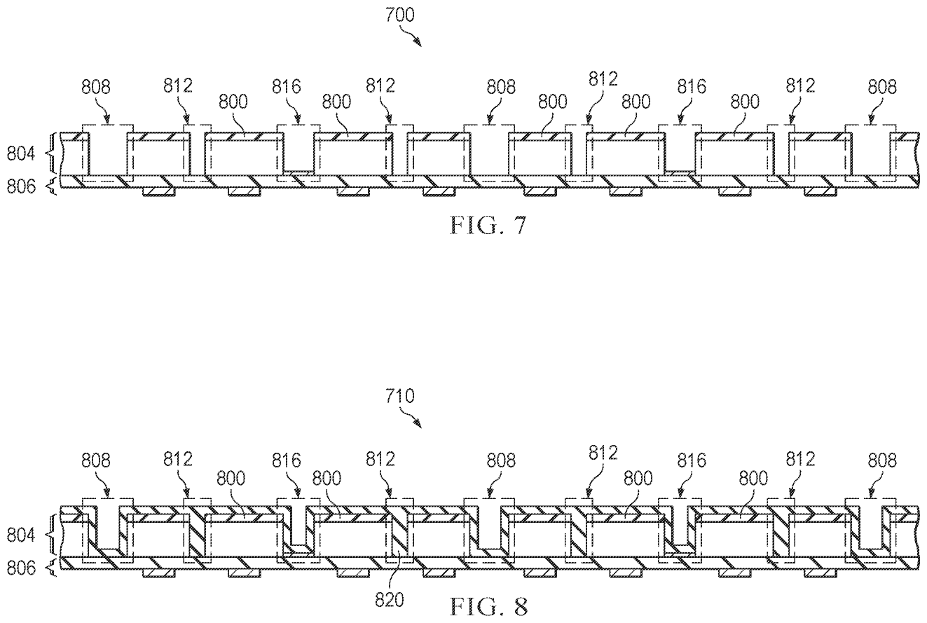

As illustrated in FIG. 8, at 710, in a second stage, a layer of a polymer dielectric 820 (e.g., parylene) is deposited on the wafer 804. The polymer dielectric 820 fills the isolation trenches 812. The polymer dielectric 820 is deposited with layers on side walls of the trenches being thicker than a bottom layer. Also, the polymer dielectric 820 partially fills the die separation trenches 808 and the via trenches 816.

At illustrated in FIG. 9, at 720, in a third stage, an etchback is applied to the polymer dielectric 820 to open a bottom and top of the die separation trenches 808 and the via trenches 816, such that the die separation trenches 808 and the via trenches 816 extend to the metallization stack 806. In some examples, the die separation trenches 808 and the via trenches 816 are etched using a patterned etch with mask layer before the etch or by using an anisotropic etch where a layer of polymer dielectric is removed vertically but a small amount (e.g., 0-5%) horizontally. In the non-patterned situation, the polymer dielectric is thinned roughly the same amount vertically. In the example of the non-patterned dielectric etch, the polymer is removed above the substrate exposing the dielectric layer (if present). In some example, the etchback of the polymer dielectric 820 includes reducing an ambient temperature to a cryogenic level (e.g., about 77 kelvin (K) or less) and using a layer to remove the polymer dielectric 820. Reducing the ambient temperature to the cryogenic level reduces stretching of the polymer dielectric 820 before a facture occurs.

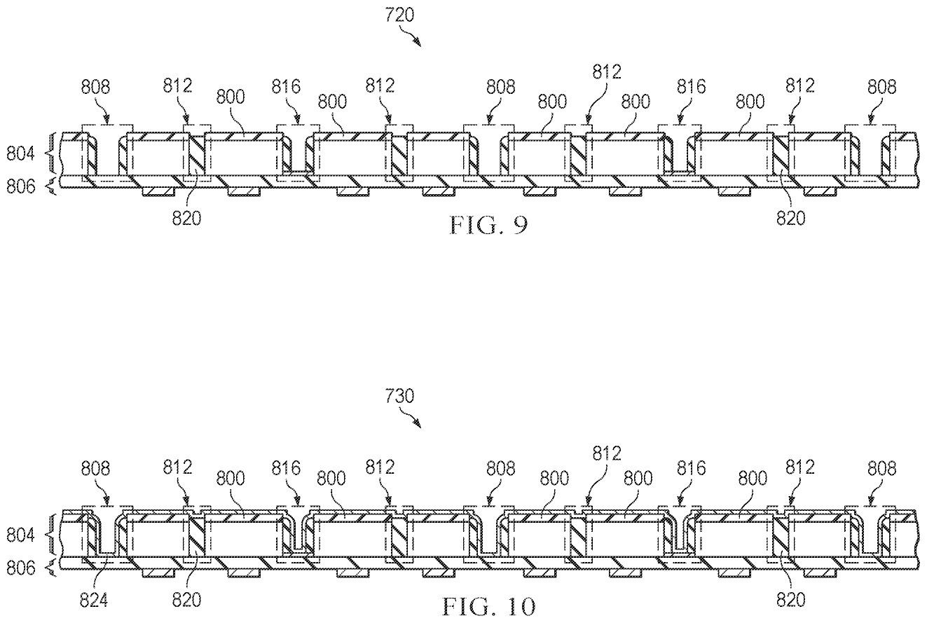

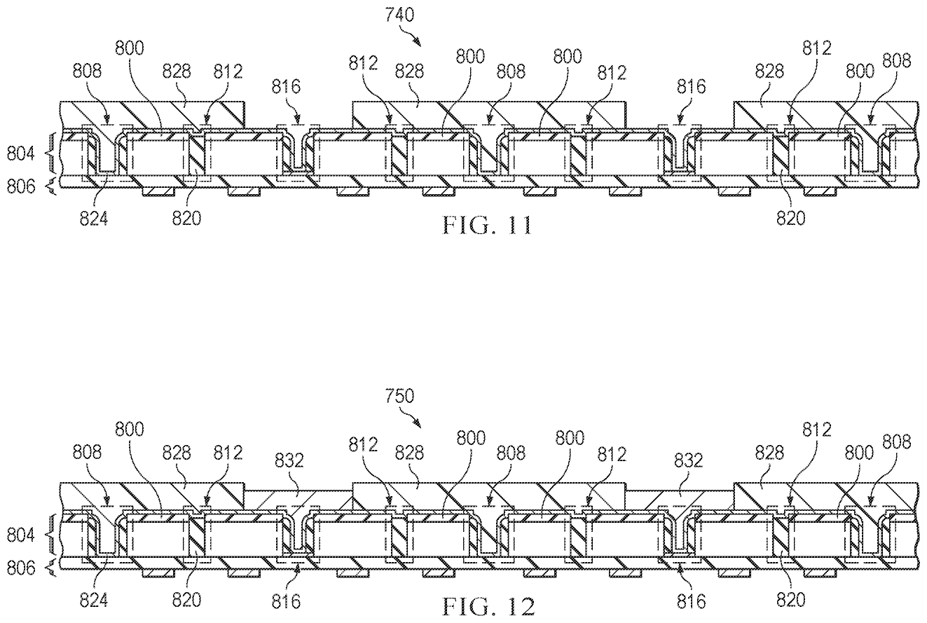

As illustrated in FIG. 10, at 730, a barrier and seed 824 formed of titanium tungsten (TiW) barrier and a copper (Cu) seed is formed on a top layer of the wafer 804. In some examples, the barrier and seed 824 are applied with physical vapor deposition (PVD). As illustrated in FIG. 11, at 740, a coat of resist coat 828 is applied an patterned on the barrier and seed 824. The resist coat 828 includes openings for the via trenches 816. As illustrated in FIG. 12, at 750, copper (Cu) or another metal is electroplated in a bottom-up process to fill the via trenches 816 to form isolation through vias 832, such as the through via 216 of FIG. 2. Accordingly, the die separation trenches 808 are masked at 740, such that the thick metal filling the via trenches 816 is not present in the die separation trenches 808.

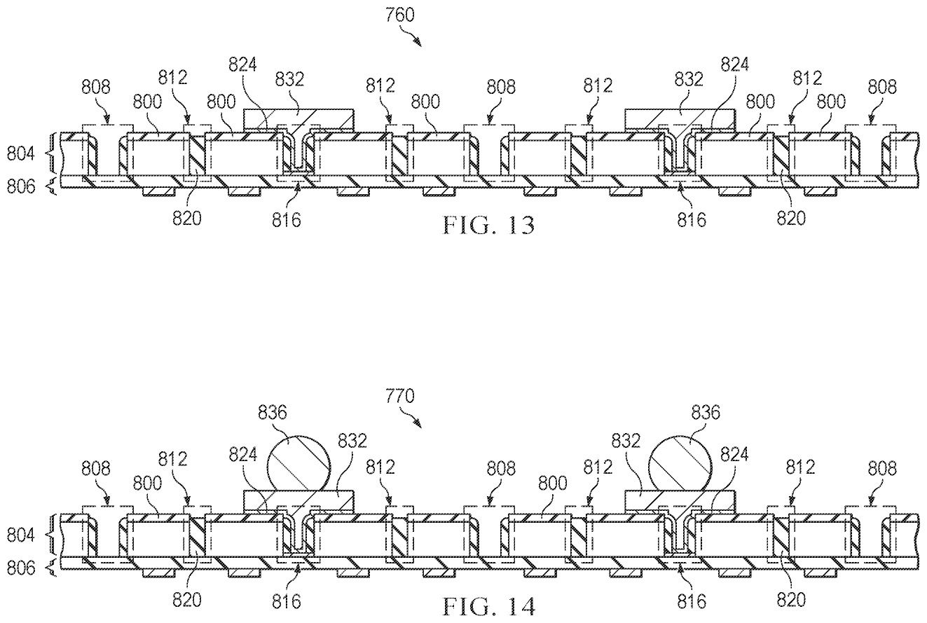

As illustrated in FIG. 13, at 760, a remaining portion of the resist coat 828, and the barrier and seed 824 are removed with a wet etching process. As illustrated in FIG. 14, at 770, solder balls 836 are attached to the through vias 832. Also, in various examples the die separation trenches 808 are cut with a laser, a ion beam or a mechanical process (e.g., a sawing, bending, application of water, a spray, etc.) to singulate dies from the wafer 1000 for further processing (e.g., packaging). In some examples, the polymer is not removed and the die are separated mechanically. For instance, in at least one example, mechanical separation is executed with a rolling technique and/or a stretch technique at room temperature or low temperatures (e.g., about 97 kelvin (K) or less). Low temperature is employed in situations where the polymer remains because the polymer becomes more brittle and less ductile at lower temperatures. Another technique includes removing the polymer in a singulation region through laser etching either from the frontside or the backside. In various examples, this laser etching removes just the polymer followed by mechanical separation or the laser etching removes or fractures the polymer as well as the dielectrics and metals in the singulation region.

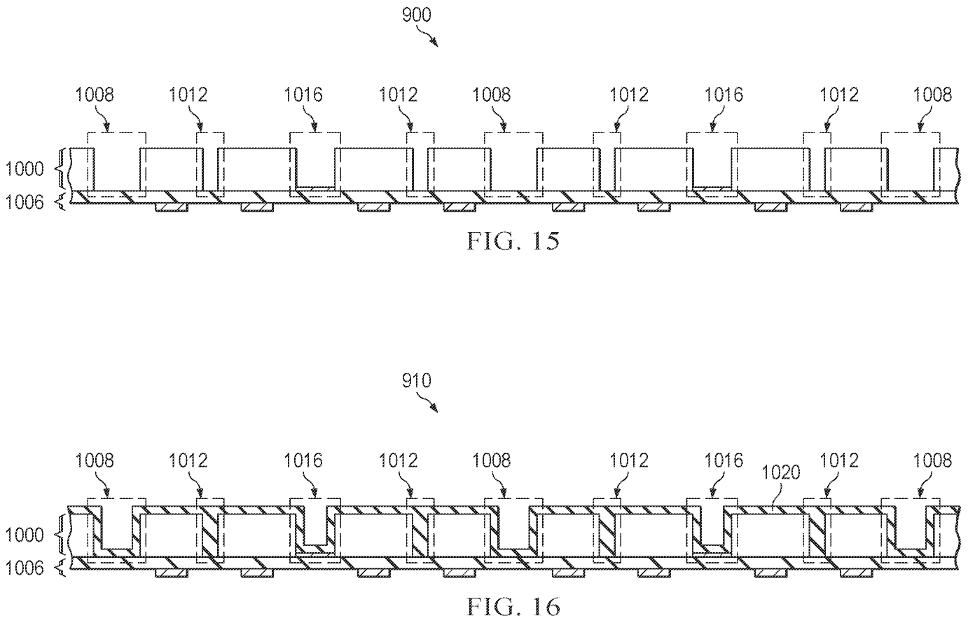

FIGS. 15-22 illustrate stages of another method for fabricating dies from a wafer 1000, such as the die 100 of FIG. 1, the die 200 of FIG. 2, the first die 304 of FIG. 3. The method of FIGS. 15-22 illustrate how the wafer is processed to add through trenches for isolation trenches, through vias and die separation trenches for dies that are employable in an IC chip, such as the IC chip 300 of FIG. 3.

As illustrated in FIG. 15, at 900, through trenches in the wafer 1000 are formed (with the application of a photoresist and/or an etch) to provide regions of the substrates that are separated by the through trenches. The wafer 1000 is employable to implement the wafer 500 of FIGS. 5A and 5B and/or the wafer 600 of FIGS. 6A and 6B.

The through trenches include die separation trenches 1008, isolation trenches 1012 and via trenches 1016. As illustrated, the isolation trenches 1012 have a first width, the via trenches 1016 have a second width and the die separation trenches 1008 have a third width, wherein the third width is greater than the second width, and the second width is greater than the first width. Forming the isolation trenches 1012 with more narrow trenches (relative to the die separation trenches 1008 and the via trenches 1016) curtails metal penetrating into the isolation trenches 1012.

As illustrated in FIG. 16, at 910, in a second stage, a layer of a polymer dielectric 1020 (e.g., parylene) is deposited on the wafer 1000. The polymer dielectric 1020 fills the isolation trenches 1012. The polymer dielectric 1020 is deposited with layers on side walls of the trenches being thicker than a bottom layer. Also, the polymer dielectric 1020 partially fills the die separation trenches 1008 and the via trenches 1016. Stated differently, a recess of the polymer dielectric 1020 is formed in the die separation trenches 1008 (trenches with the third width) and via trenches 1016 (trenches with the second width). Conversely, the isolation trenches 1012 are sufficiently narrow such that the polymer dielectric 1020 fills the isolation trenches 1012 completely (or with in 5%).

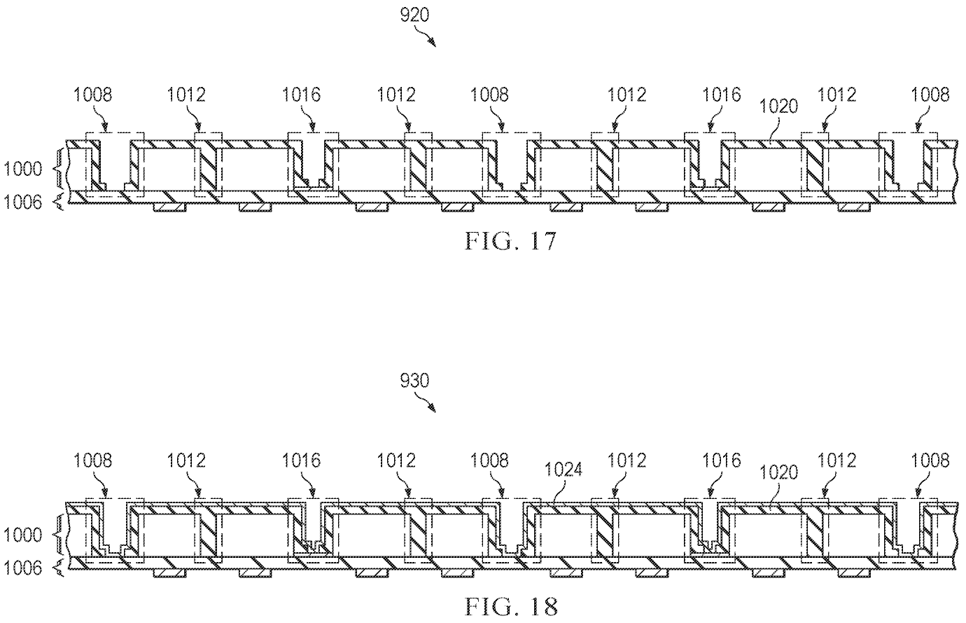

At illustrated in FIG. 17, at 920, in a third stage, the polymer dielectric 1020 is etched to open a bottom the die separation trenches 1008 and the via trenches 1016, such that the die separation trenches 1008 and the via trenches 1016 extend to the metallization stack 1006. In some examples, the die separation trenches 1008 and the via trenches 1016 are etched using a patterned etch with mask layer before the etch or by using an anisotropic etch where a layer of polymer dielectric is removed vertically but a small amount (e.g., 0-5%) horizontally. In the non-patterned situation, the polymer dielectric is thinned roughly the same amount vertically. In the example of the non-patterned dielectric etch, the polymer is removed above the substrate exposing the optional dielectric layer. In some examples, etching of the polymer dielectric 1020 is executed with a plasma cutter, a laser or a ion beam. Further, in some examples, prior to etching the polymer dielectric 138, an ambient temperature of the wafer 1000 is reduced to a cryogenic level (e.g., about 97 kelvin (K) or less). Reducing the ambient temperature to the cryogenic level reduces stretching of the polymer dielectric 1020 before a facture occurs.

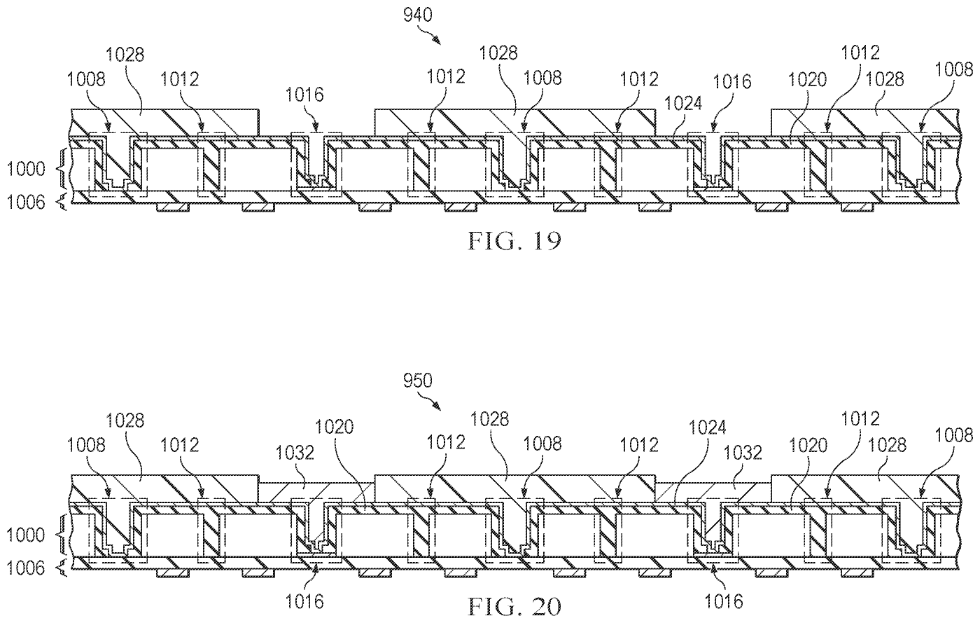

As illustrated in FIG. 18, at 930, a barrier and seed 1024 formed of a titanium tungsten (TiW) barrier and a copper (Cu) seed is formed on a top layer of the wafer 1000. In some examples, the barrier and seed 1024 are applied with PVD. As illustrated in FIG. 19, at 940, a coat of resist coat 1028 is applied an patterned on the barrier and seed 1024. The resist coat 1028 includes openings for the via trenches 1016. As illustrated in FIG. 20, at 950, copper (Cu) or another metal is electroplated in a bottom-up process to fille the via trenches 1016 to form isolation through vias 1032, such as the through via 216 of FIG. 2.

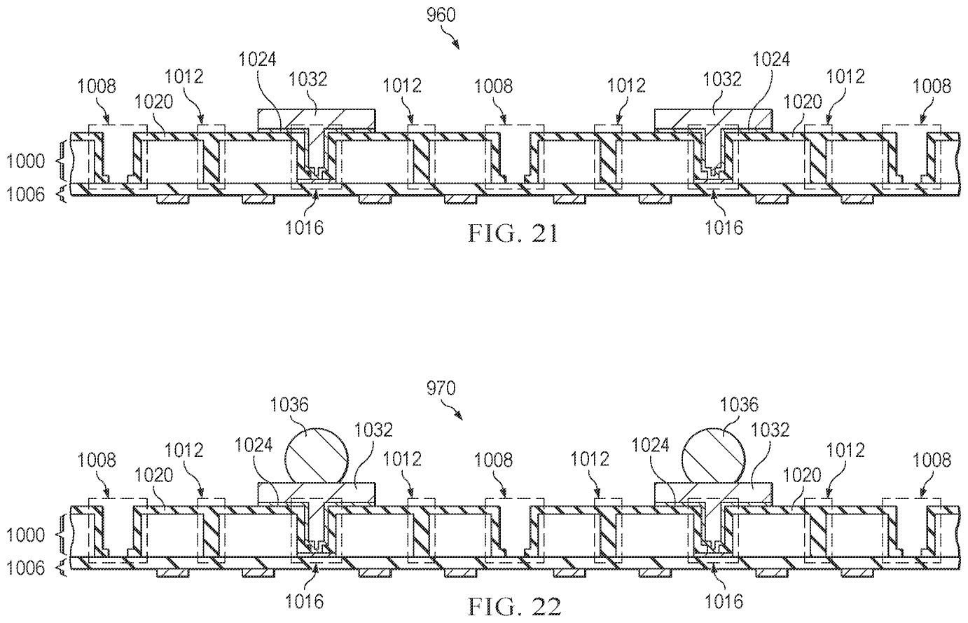

As illustrated in FIG. 21, at 960, a remaining portion of the resist coat 1028, and the barrier and seed 1024 are removed with a wet etching process. As illustrated in FIG. 22, at 970, solder balls 1036 are attached to the through vias 1032. Also, in various examples the die separation trenches 1008 are cut with a laser, a ion beam or a mechanical process (e.g., a sawing, separation, bending, application of water, a spray, etc.) to singulate dies from the wafer 1000 for further processing (e.g., packaging). In some examples, the polymer is not removed and the die are separated mechanically. For instance, in at least one example, mechanical separation is executed with a rolling technique and/or a stretch technique at room temperature or low temperatures (e.g., about 97 kelvin (K) or less). Low temperature is employed in situations where the polymer remains because the polymer becomes more brittle and less ductile at lower temperatures. Another technique includes removing the polymer in a singulation region through laser etching either from the frontside or the backside. In various examples, this laser etching removes just the polymer followed by mechanical separation or the laser etching removes or fractures the polymer as well as the dielectrics and metals in the singulation region. Dies formed by the method 900 are employable to fabricate high voltage (e.g., 300 V or more) devices in a relatively compact area. Some examples have a minimum spacing between exposed wires from different voltage regions due to a poor electric field capability of the mold compound. With electrical connections available from both sides it is possible to attach bump connections to a lower lead frame for one or more voltage regions. In such a situation, other voltage regions(s) are connectable with wire bond connections to another side of the package. In this manner, a reduced sized package is enabled without sacrificing high voltage differences (e.g., about 300 V or more) and without increasing costs of fabrication. This allows a small form factor for the package for high voltage products (e.g., products with a voltage rating of about 300 V or more).

As compared to the process illustrated in FIGS. 7-14, the process illustrated in FIGS. 15-22 does not need an etchback to open the die separation trenches 1008 or the via trenches 1016.

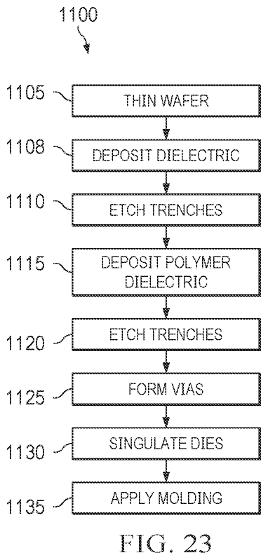

FIG. 23 illustrates a flowchart of an example method 1100 for processing a wafer to form IC chips, such as the IC chip 300. In various examples, the wafer is implemented with the wafer 804 of FIGS. 7-14 or the wafer 1000 of FIG. 15-22. At 1105, the wafer is thinned so that a front surface is down on a silicon (Si) carrier wafer or tape on frame for further processing. At 1008, a dielectric layer is deposited on a backside of the wafer. In various examples, the dielectric layer is silicon nitride (SiN), silicon dioxide (SiO₂), spin on glass, hydrogen silsesquioxane (HSQ), silicon oxynitride (SiON), silicon carbide (SiC), silicon carbon oxynitride (SiCON), aluminum nitride (AlN), aluminum oxide (Al₂O₃), boron nitride (BN), diamond like carbon or a polymer such as polyimide or parylene. At 1110, through trenches are etched in the wafer to form regions of substrates on the backside of the wafer. The trenches are etched in the wafer to form regions of substrates. In some examples, the trenches are etched through the wafer stopping on or in the dielectrics on the frontside of the silicon wafer. The regions of substrates are separated by through trenches of a first width, a second width or a third width. The first width is less than the second width and the second width is less than the third width. The through trenches of the first width are referred to as isolation trenches (e.g., the isolation trenches 812 of FIGS. 7-14 or the isolation trenches 1012 of FIGS. 15-22). The through trenches of the second width are referred to as via trenches (e.g., the via trenches 816 of FIGS. 7-14 or the via trenches 1016 of FIGS. 15-21). The through trenches of the third width are referred to as die separation trenches (e.g., the die separation trenches 808 of FIGS. 7-14 or the die separation trenches 1008 of FIG. 15-22).

At 1115, a polymer dielectric (e.g., the polymer dielectric 820 of FIGS. 7-14 or the polymer dielectric 1020 of FIGS. 15-22) is deposited on the wafer. The through trenches are shaped such that a recess of the polymer dielectric is formed in the via trenches and the die separation trenches. At 1120, the die separation trenches and the via trenches are etched to expose an underlying metallization stack. In some examples, the die separation trenches and the via trenches are etched using a patterned etch with mask layer before the etch or by using an anisotropic etch where a layer of polymer dielectric is removed vertically but a small amount (e.g., 0-5%) horizontally. In the non-patterned situation, the polymer dielectric is thinned roughly the same amount vertically. In the example of the non-patterned dielectric etch, the polymer is removed above the substrate exposing the optional dielectric layer. At 1125, through vias (e.g., the through vias 832 of FIGS. 12-14 or the through vias 1032 of FIGS. 20-22) are formed in the via trenches. At 1130, dies are singulated from the wafer by cutting the trenches of the third width such that the dies include the through vias and the isolation trenches (e.g., trenches of the first width and the second width). The singulation at 1130 is executable with a selected technique. In some examples, the polymer is not removed and the die are separated mechanically. For instance, in at least one example, mechanical separation is executed with a rolling technique and/or a stretch technique at room temperature or low temperatures (e.g., about 97 kelvin (K) or less). Low temperature is employed in situations where the polymer remains because the polymer becomes more brittle and less ductile at lower temperatures. Another technique includes removing the polymer in a singulation region through laser etching either from the frontside or the backside. In various examples, this laser etching removes just the polymer followed by mechanical separation or the laser etching removes or fractures the polymer as well as the dielectrics and metals in the singulation region. At 1135, the dies are packaged, such that the dies are mounted on an interconnect (e.g. the interconnect 312 of FIG. 3) and encased in molding (e.g., the molding 314 of FIG. 3).

Modifications are possible in the described embodiments, and other embodiments are possible, within the scope of the claims.

What is claimed is:

1. A device comprising:
a die with a metallization stack;
a substrate with a first region, a second region and a third region that underly the metallization stack;
a first isolation trench filled with a polymer dielectric that extends between the first region and the second region of the substrate; and
a second isolation trench filled with the polymer dielectric that extends between the second region and the third region, wherein the polymer dielectric overlays a periphery of the substrate.

2. The device of claim 1, wherein the first isolation trench extends from a first edge on the periphery of the substrate to a second edge on the periphery of the substrate, the first edge being parallel to the second edge.

3. The device of claim 2, wherein the first isolation trench is linear.

4. The device of claim 2, wherein the first isolation trench is non-linear.

5. The device of claim 2, wherein the second isolation trench is in the third region of the substrate and has a rectangular shape that circumscribes the second region.

6. The device of claim 1, wherein the first isolation trench and the second isolation trench are in the first region of the substrate, and the first isolation trench circumscribes the second region of the substrate, and the second isolation trench circumscribes the third region of the substrate.

7. The device of claim 6, wherein the first isolation trench and the second isolation trench have a rectangular shape.

8. The device of claim 1, wherein the die comprises a through via that provides an electrical connection between a first surface of the die and a second surface of the die, and the first surface opposes the second surface.

9. The device of claim 8, wherein the die is coupled to pads of an interconnect.

10. The device of claim 8, wherein the die is a first die, the device comprises a second die, and the second die is coupled to one of the pads of the interconnect across the through via of the first die.

11. The device of claim 8, wherein a wire bond is coupled to one of the pads of the interconnect across the through via of the first die.

12. The device of claim 8, wherein the substrate comprises silicon, and the polymer dielectric comprises parylene.

13. A method for forming a die, the method comprising:
depositing a polymer dielectric on a wafer, the wafer comprising regions of substrates, wherein the regions of substrates are separated by trenches of a first width, a second width or a third width, the first width being less than the second width, and the second width being less than the third width, wherein a recess of the polymer dielectric is formed over the trenches of the first width and the second width;
etching the trenches of the second width and the third width to expose a metallization stack;
forming through vias in the trenches of the second width; and
singulating dies by dicing the wafer at the trenches of the third width, such that the dies comprise the trenches of the second width and through vias formed in the trenches of the third width.

14. The method of claim 13, wherein forming the through vias in the trenches of the second width further comprises:
reducing an ambient temperature of the wafer to 77 Kelvin (K) or less; and
applying etchback to the trenches of the second width and the third width to expose the metallization stack underlying the trenches of the second width and the third width.

15. The method of claim 14, wherein forming the vias in the trenches of the second width further comprises:
applying a barrier and seed with a physical vapor deposition;
applying a resist coating on the barrier and seed; and
etching the resist coating to expose the trenches of the second width.

16. The method of claim 15, wherein forming the vias in the trenches of the second width further comprises:
electroplating metal in the exposed trenches of the second width;
removing a remaining portion of the resist coating and the barrier and seed; and
attaching solder balls to the metal electroplated in the trenches of the second width.

17. The method of claim 13, wherein forming the vias in the trenches of the second width further comprises:
etching the trenches of the first width and the second width to expose the dielectric underlying the trenches of the first width and the second width.

18. The method of claim 17, wherein the etching is executed with one of a plasma cutter, a laser or an ion beam.

19. The method of claim 17, wherein forming the vias in the trenches of the second width further comprises:
applying a barrier and seed with a physical vapor deposition;
applying a resist coating on the barrier and seed;
etching the resist coating to expose the trenches of the second width;
electroplating metal in the exposed trenches of the second width;
removing a remaining portion of the resist coating and the barrier and seed; and
attaching solder balls to the metal electroplated in the trenches of the second width.

20. The method of claim 19, wherein forming the vias in the trenches of the second width further comprises:
electroplating metal in the exposed trenches of the second width;
removing a remaining portion of the resist coating; and
attaching solder balls to the metal electroplated in the trenches of the second width.
